(19) United States
(12) Patent Application Publication
(10) Pub. No.: US 2008/0024985 A1
(43) Pub. Date: Jan. 31, 2008

(54) Computer casing with high heat dissipation efficiency

(76) Inventors: Zong-Jui Lee, Taipei Hsien (TW); Zhong-Yang Chang, Taipei Hsien (TW)

Correspondence Address: ZONG-JUI LEE, 235 Chung- Ho, Box 8-24, Taipei, omitted

(21) Appl. No.: 11/495,699

(22) Filed: Jul. 31, 2006

(51) Int. Cl. H05K 7/20

(52) U.S. Cl. 361/695

(57) ABSTRACT

A computer casing with high heat dissipation efficiency comprises a lateral plate at an outer side of the supporting seat; a fan installed on the lateral plate; a supporting seat installed at an inner side of the lateral plate; a mother board installed to have a predetermined space to the supporting seat; a processing unit of a computer on the mother board; and a flow guide plate installed between the lateral plate and the flow guide plate; the flow guide plate being formed with a plurality of through holes at positions corresponding to those of the fan for sucking air to the fan; the flow guide plate having a plurality of ribs at an outer side thereof; the ribs being formed as flow channels for guiding air in the computer casing to the fan. The flow guide plate has a plurality of via holes which are arranged randomly on the flow guide plate; and edges of the flow guide plate have a plurality of edge holes.

### FIELD OF THE INVENTION

The present invention relates to computer casings, in particular to a computer casing with high heat dissipation efficiency, wherein a plurality of paths serve to provide air to the fan so that more hot air is guided to the fan. Moreover, the space for installing the fan is enlarged so that large scale fan or a plurality of fans can be installed.

### BACKGROUND OF THE INVENTION

Heat dissipation is important in electronic devices since the electronic device dissipates a great amount of heat which is necessary to be dissipated.

One of heat dissipation technology is disclosed in FIG. 1, in that a computer heat dissipation for CUP of a computer mainframe is disclosed. An auxiliary heat dissipation device 70 is installed in the computer mainframe 71. The auxiliary heat dissipation device 70 has an auxiliary fan 73 fixed to a bottom plate 72 of a backside of the mainframe. The auxiliary fan 73 is controlled by a control circuit in the computer mainframe 71 and faces toward the backside of a CPU corresponding to the mother board for dissipating heat of the CPU.

However in use, the space for installing the auxiliary fan 73 at the bottom plate 72 is not sufficient, in particular to height. Thus, the scale and number of the fan are limited. Moreover, because the fan is installed at the backside of the CPU, it only sucks hot air about the CPU. The heat dissipation efficiency is limited.

### SUMMARY OF THE INVENTION

Accordingly, the primary object of the present invention is to provide a computer casing with high heat dissipation efficiency, wherein a plurality of paths are provided air to the fan so that more hot air is guided to the fan. Moreover, the space for installing the fan is enlarged so that a large scale fan or a plurality of fans can be installed.

To achieve above objects, the present invention provides a computer casing with high heat dissipation efficiency which comprises a lateral plate at an outer side of the supporting seat; a fan installed on the lateral plate; a supporting seat installed at an inner side of the lateral plate; a mother board installed to have a predetermined space to the supporting seat; a processing unit of a computer on the mother board; and a flow guide plate installed between the lateral plate and the flow guide plate; the flow guide plate being formed with a plurality of through holes at positions corresponding to those of the fan for sucking air to the fan; the flow guide plate having a plurality of ribs at an outer side thereof; the ribs being formed as flow channels for guiding air in the computer casing to the fan. The flow guide plate has a plurality of via holes which are arranged randomly on the flow guide plate; and edges of the flow guide plate have a plurality of edge holes. The supporting seat has a plurality of through holes corresponding to the through holes of the flow guide plate, via holes randomly formed on the supporting seat and edge holes near the edges thereof. The lateral plate is installed at a frame body of the computer casing for installing the fan to such air in the computer casing. The computer casing is installed the casing of a personal computer, a servo computer and an industry computer. The through holes of the flow guide plate are arranged at a swirl shape and the ribs of the flow guide plate are arranged as a swirl shape lead to the through holes of the flow guide plate.

The various objects and advantages of the present invention will be more readily understood from the following detailed description when read in conjunction with the appended drawing.

### BRIEF DESCRIPTION OF THE DRAWINGS

FIG. 1 shows the fan installation in the prior art structure.

FIG. 2 shows the prior art heat dissipation module.

FIG. 3 shows the perspective view of the computer casing of the present invention.

FIG. 4 shows the schematic view about the lateral plate, fan and flow guide plate of the present invention.

FIG. 5 shows the schematic view about the flow guide plate and supporting seat of the present invention.

FIG. 6 shows the schematic cross sectional view of the present invention.

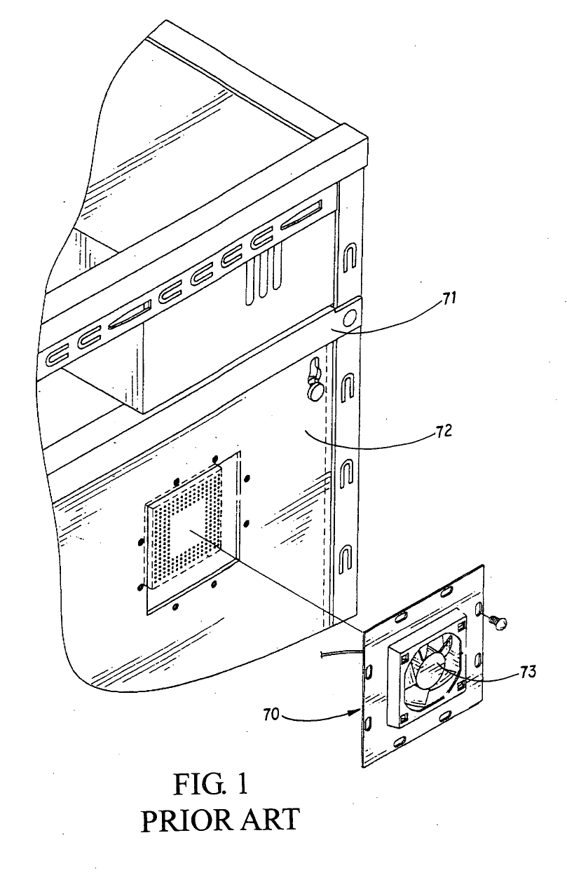

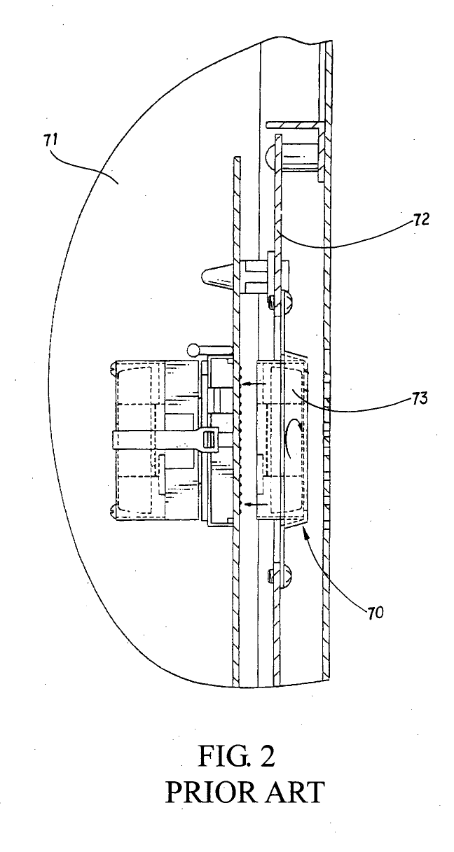

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

It should be known that to install a heat dissipation module on a computer processing unit or a fan installed at a rear side of a casing is known in the prior art and thus the details will not be described herein.

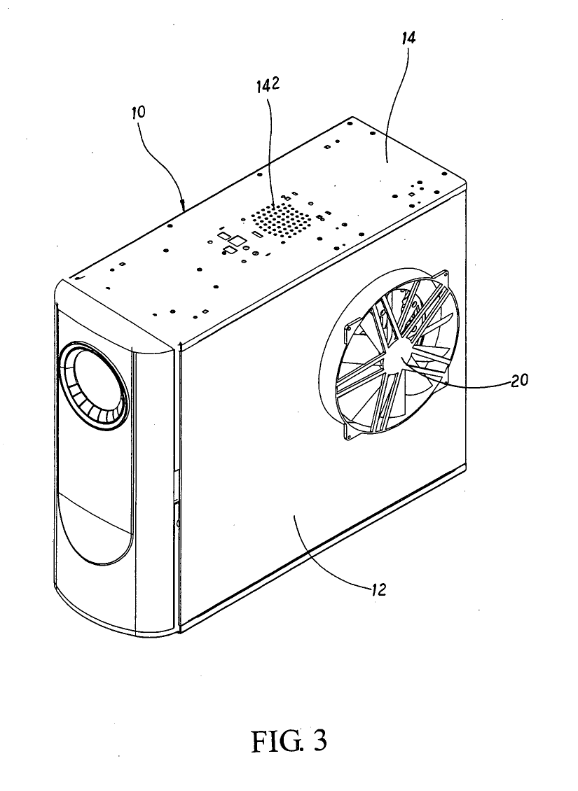

Referring to FIG. 3, a perspective view of a computer casing with a predetermined type is illustrated. However the present invention is not confine to a computer mainframe, other devices, such as a servo computer or an industrial computer is also within the scope of the present invention. The element of the present invention will be described herein.

A computer casing 10 has a lateral plate 12. A fan 20 is installed on the lateral plate 12 for sucking hot air and transferring hot air out of the computer casing 10.

An upper plate 14 is formed at an upper side of the computer casing 10. The upper plate 14 is formed with a plurality of air holes 142 for sucking external cool air into the computer casing 10. The main heat source in the computer casing 10 is the processing unit. The higher the clock speed, the greater the heat dissipated. The area of the fan includes the processing unit.

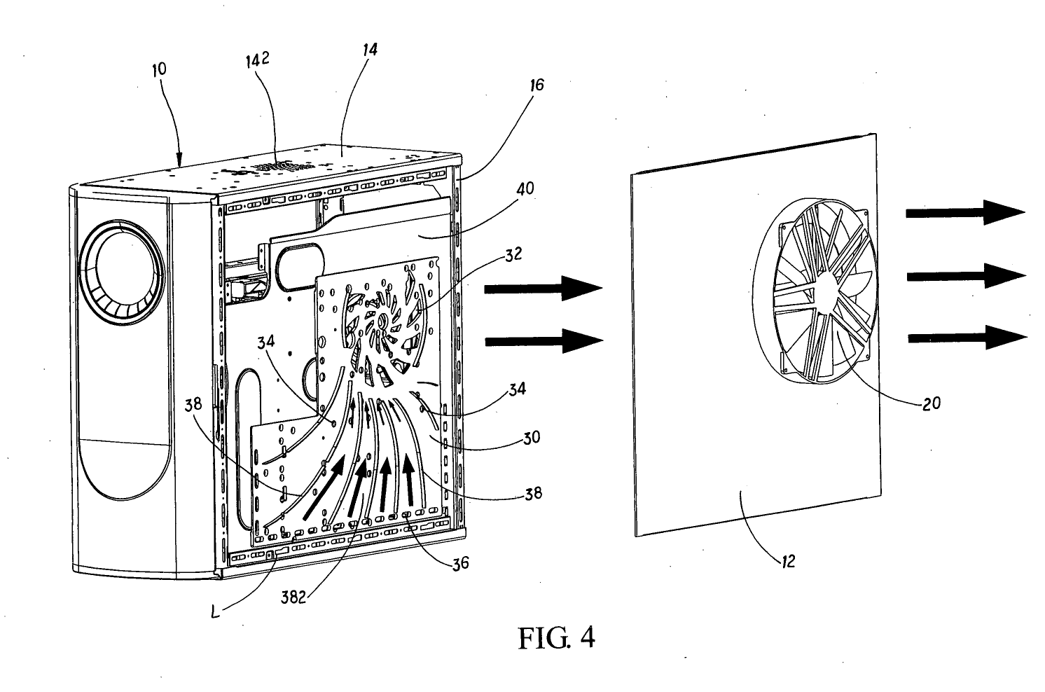

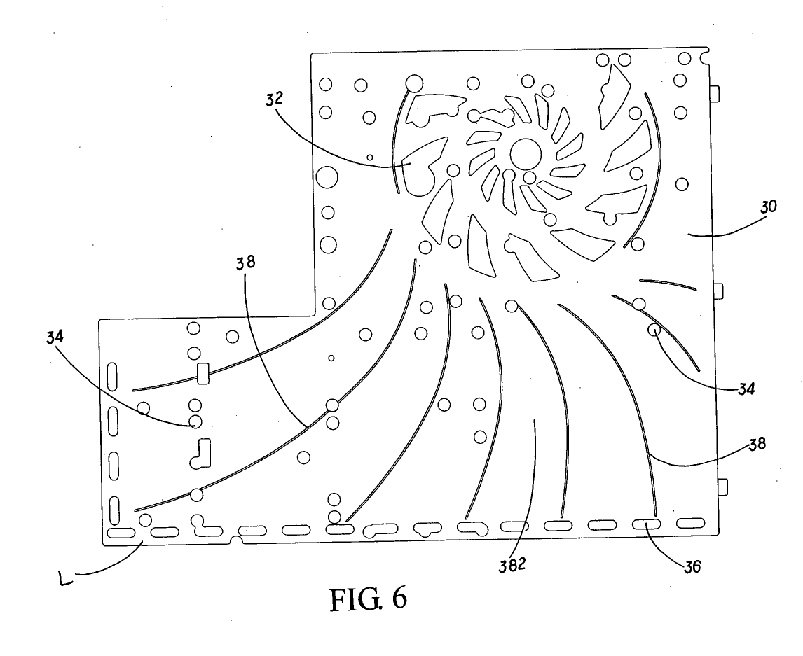

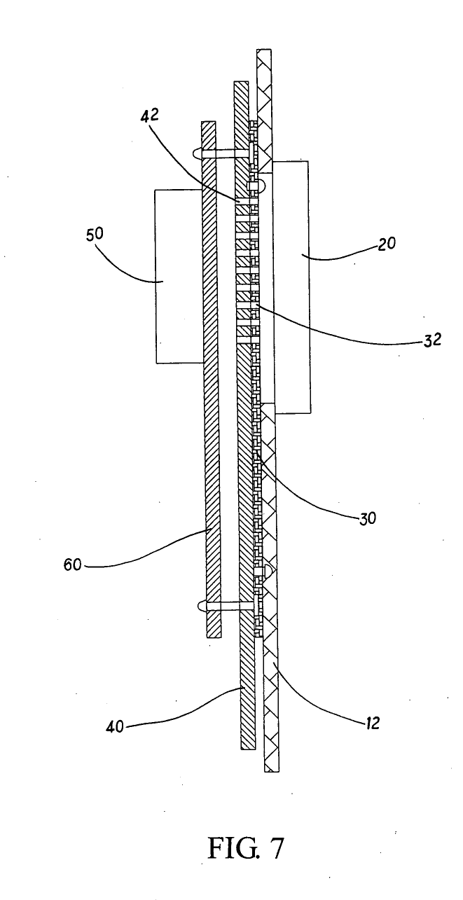

Referring to FIGS. 4 and 6, the fan 20 is installed on the lateral plate 12 for matching the scale of the frame body 16. The number of the fan 20 is not confined to one. More than one fans 20 can be installed, which can be formed as a fan set or a large scale fan 20 can be used.

A flow guide plate 30 is installed at an inner side of the lateral plate 12 and a supporting seat 40 is installed at an inner side of the flow guide plate 30. The flow guide plate 30 is formed with a plurality of through holes 32 which are formed as a swirl shape and a plurality of via holes 34 which are arranged randomly on the flow guide plate 30. A plurality of curved ribs 38 are formed on the outer side of the flow guide plate 30. The ribs 38 are arranged from the edges of the flow guide plate 30 to the through hole 32. The spaces between the adjacent ribs 38 are formed as flow channels 382. Thus hot air in the computer casing 10 flows along the channel 382 to the fan 20 so as to be dissipated by the fan. Thus hot air in the computer casing 10 can passes through the through hole 32 to the fan and other hot air far away from the through hole 32 can be guided to the fan 20 through the channels 382.

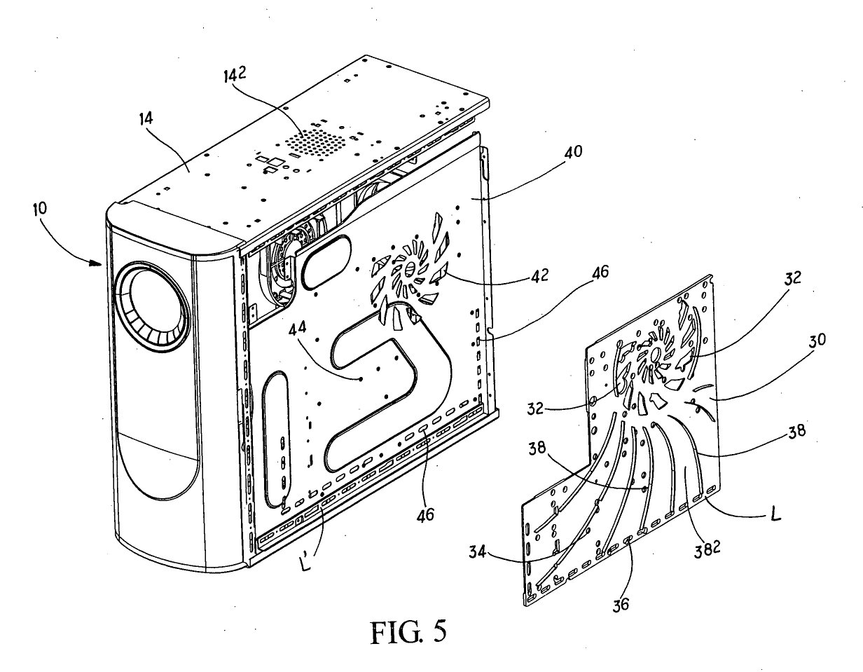

Referring to FIG. 5, a motherboard 60 is installed on the supporting seat 40 with a predetermined space to the mother board 60, as illustrated in FIG. 7. The supporting seat 40 is formed with a plurality of through holes 42 at positions corresponding to those of heat sources and via holes 44. A plurality of edge holes 46 are formed at location L′ near edges of the supporting seat 40. The flow guide plate 30 is adhered to one side of the supporting seat 40. The through holes 32 of the flow guide plate 30 are at positions corresponding to those of the through holes 42. The structure and configuration of the flow guide plate 30 have been described hereinabove. It will not be described herein.

Referring to FIG. 7, the cross sectional view about the components of computer casing 10 of the present invention is illustrated. The processing unit 50 is installed in the motherboard 60. The motherboard 60 is installed above the supporting seat 40 with a predetermined space thereto. The through holes 42 are formed at the backside of the processing unit 50. The flow guide plate 30 is installed with through holes 32 at position corresponding to that of the supporting seat 40. Thus, the hot air at the rear side of the processing unit 50 is drained out through the through holes 42 of the supporting seat 40, the through holes 32 of the flow guide plate 30, and the fan 20 of the lateral plate 12. Another path for draining the hot air in the computer casing 10 (referring to FIGS. 4 and 5) is formed by the via holes 44 of the supporting seat 40, the edge holes 46 of the supporting seat 40, the via holes 34 and edge holes 36 of the flow guide plate 30 and then the channels 382 of the ribs 38 of the flow guide plate 30 to the fan 20 so that hot air is concentrated to fan. Thus hot air at the backside of the processing unit 50 and within the computer casing 10 can be transferred out. Thus the heat dissipation is high efficiency.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A computer casing with high heat dissipation efficiency, comprising:
a lateral plate at an outer side of the supporting seat;
a fan installed on the lateral plate;
a supporting seat installed at an inner side of the lateral plate; a mother board installed to have a predetermined space to the supporting seat; a processing unit of a computer on the mother board; and
a flow guide plate installed between the lateral plate and the flow guide plate; the flow guide plate being formed with a plurality of through holes at positions corresponding to those of the fan for sucking air to the fan; the flow guide plate having a plurality of ribs at an outer side thereof; the ribs being formed as flow channels for guiding air in the computer casing to the fan.

2. The computer casing with high heat dissipation efficiency as claimed in claim 1, wherein the flow guide plate has a plurality of via holes which are arranged randomly on the flow guide plate; and edges of the flow guide plate have a plurality of edge holes.

3. The computer casing with high heat dissipation efficiency as claimed in claim 1, wherein the supporting seat has a plurality of through holes corresponding to the through holes of the flow guide plate, via holes randomly formed on the supporting seat and edge holes near the edges thereof.

4. The computer casing with high heat dissipation efficiency as claimed in claim 1, wherein the lateral plate is installed at a frame body of the computer casing for installing the fan to such air in the computer casing.

5. The computer casing with high heat dissipation efficiency as claimed in claim 1, wherein the computer casing is one of a casing of a personal computer, a casing of a servo computer and a casing an industry computer.

6. The computer casing with high heat dissipation efficiency as claimed in claim 1, wherein the through holes of the flow guide plate are arranged as a swirl shape and the ribs of the flow guide plate are arranged as a swirl shape lead to the through holes of the flow guide plate.
